(19) United States
(12) Patent Application Publication
(10) Pub. No.: US 2014/0043089 A1
(43) Pub. Date: Feb. 13, 2014

(54) DIGITALLY CONTROLLED HIGH SPEED HIGH VOLTAGE GATE DRIVER CIRCUIT

(71) Applicants: Sven Schiller, Erlangen (DE); Helmut Mrusek, Hamburg (DE)

(72) Inventors: Sven Schiller, Erlangen (DE); Helmut Mrusek, Hamburg (DE)

(73) Assignee: KONINKLIJKE PHILIPS N.V., EINDHOVEN (NL)

(21) Appl. No.: 14/113,932

(22) PCT Filed: Apr. 2, 2012
(86) PCT No.: PCT/IB12/51608

§ 371 Date: Oct. 25, 2013

(30) Foreign Application Priority Data
Apr. 28, 2011 (EP) 11163988.6

(51) Int. Cl. H03K 17/042

(52) U.S. Cl. CPC H03K 17/04206
USPC 327/376

(57) ABSTRACT

The present invention relates to semiconductor technology. In particular, the present invention relates to high-speed, high voltage switching for a high voltage generator for an X-ray system. Switching elements, e.g. IGBTs or MOS-FETs, are employed for high-speed high voltage switching. However, circuit elements or parasitic elements at an input of the switching element limit the switching speed of the switching element. The present invention proposes applying a higher than allowed voltage to the input of the switching element, e.g. a voltage higher than the maximum allowed gate voltage of an IGBT or MOS-FET, to increase switching speed. A feedback loop is provided for save operation. thus, a switching circuit (20) for high speed switching is provided, comprising an amplifier circuit (22), comprising an output (8a) being adapted to be connectable to an input (8b) of a switching arrangement (2), wherein the voltage provided by the output (8a) exceeds a maximum gate voltage, wherein the amplifier circuit (22) is controllable so that a current internal gate voltage does not to exceed the maximum internal gate voltage.

### FIELD OF THE INVENTION

The present invention relates to power semiconductor technology. Particularly, it relates to high voltage generator technology, e.g. for X-ray systems. In particular, the present invention relates to a switching arrangement, a switching circuit and a switching circuit arrangement for high-speed switching, an X-ray apparatus comprising a switching arrangement, a switching circuit or a switching circuit arrangement according to the present invention, a method for high-speed switching, a computer-readable medium, a program element and a processing device.

### BACKGROUND OF THE INVENTION

In current high voltage generators, e.g. for X-ray systems, switching elements like e.g. insulated gate bipolar transistors (IGBT) or metal oxide semiconductor field effect transistors (MOS-FET) are employed. Such switching elements are regularly driven with a voltage source provided to an input of the switching element to control a switching on and off of the switching element. E.g., a positive voltage applied to the gate of an IGBT or a MOS-FET allows a switching on of the switching element, while zero voltage or a negative voltage provided to the gate of the switching element may result in switching off of the switching element.

In case the switching element is switched on, a subsequent high voltage or high power may be switched on likewise and be provided by an output port of the switching element to a consumer, e.g. an X-ray generator, generating high voltage or high power for an X-ray tube of an X-ray system. Said high voltage or high power is switched off and thus not provided to the consumer in case the switching element is switched off. A subsequent switching on and off may allow to modulate and thus to control a voltage or power provided to the consumer.

For further increasing the switchable high voltage or high power, a plurality of switching elements may be employed in parallel, as well.

The switching voltage of the voltage source is provided to an input of the switching element. However, parasitic elements or further circuit elements like e.g. dedicated resistive or capacitive elements may be provided between the input of the switching element and an internal input port for the actual gate of the semiconductor. Said parasitic elements or circuit elements however may result in a voltage drop between the input and the internal input port (e.g. gate) of the switching element, so resulting in that not the full applied voltage of the voltage source, applied to the input is available at the internal input port of the switching element, thus after dedicated circuit elements or parasitic elements. At least the full voltage applied to the input only arrives at the internal input port after a certain time delay due to the parasitic elements or circuit element.

Said voltage drop or time delay results in the switching speed of the switching element to be limited. In particular, parasitic elements like a parasitic inductance or a parasitic capacitance influences a slew rate of the voltage applied to the input, subsequently arriving at the internal input port of the switching element.

### SUMMARY OF THE INVENTION

It may thus be beneficial to increase the switching speed of a switching element by reducing the influence of the parasitic elements or further circuit elements arranged at the internal input port of a switching element, in particular between an input and the internal input port.

Said benefit may be provided, inter alia, by the subject-matter of the independent claims. Further preferred embodiments may be taken from the dependent claims.

Since a parasitic element, e.g. a parasitic inductance, influences a slew rate dependent on an applied voltage, a slew rate may be increased by increasing the applied voltage.

Accordingly, the present invention, inter alia, proposes to provide a voltage of a voltage source by an output of a gate driver or gate amplifier, in particular a digitally controlled gate driver, to an input of a switching element, the voltage being higher than the voltage actually allowed for the respective internal input port or internal gate port of the switching element. In other words, a higher voltage than the maximum allowed gate voltage, e.g. in the case of IGBTs or MOS-FETs, is employed for driving the gate.

E.g., one common value for driving the gate of an IGBT may be considered to be ±15 V. To increase the slew rate and thus the switching speed of the switching element, the voltage source may provide a higher voltage than 15 V, e.g. 2×, 3×, 4× or more of the gate voltage, to the input of the switching element, e.g. ±50 V.

When using an accordingly higher voltage as a gate drive voltage, the driving gate current through the internal gate resistor and parasitic elements in a gate circuit may be substantially increased, so resulting in an increase in charge and discharge of e.g., a gate capacitance of the switching element. An according increase in charging and discharging circuit capacitances may lead to an increase in switching speed of the switching element.

However, such an “overvoltage” applied to an input of a switching element may subsequently result in also the internal gate port of the switching element receiving the overvoltage and thus a higher voltage than what would be allowed at the internal gate port, e.g. specification-wise with regard to a specific switching element. In other words, in case e.g. ±50 V are employed as a switching voltage from an input voltage source, provided to the input, i.e. before parasitic elements and circuit elements, of the switching element, it may be required to assure that the voltage applied to the internal gate port, i.e. after parasitic elements and circuit elements, of the switching elements may not exceed the maximum allowed gate voltage of e.g. ±15 V.

Accordingly, a currently occurring voltage at the internal input port or internal gate port and thus directly beyond the internal gate resistor at the chip may be determined, e.g. with an additional tap port on the switching element die. Said tap port may be employed for determining the currently occurring voltage at the internal gate port on the die of the switching element and thus for example the gate of an IGBT or MOS-FET. E.g., in case the current voltage at the internal gate port of the switching element substantially equals or is about to exceed the maximum allowed gate voltage, the voltage source, employing a higher voltage than the maximum allowed gate voltage or an overvoltage, may be switched off, so hindering a further rise of the current input voltage at the internal gate port and enabling a save operation of the gate of an IGBT or MOS-FET within its specified voltage values.

A feedback loop, provided by the tap port, may subsequently determine whether the current internal voltage at the tap port and thus the internal gate voltage remains within an allowable region of the maximum allowed gate voltage. In case a drop in the applied voltage to the internal gate port is determined, the feedback loop may subsequently employ a voltage source control element to again switching on the higher voltage of the voltage source to again increase the applied internal gate port voltage.

The gist of the invention may thus be seen in providing an voltage source providing a voltage from a driver output of a gate driver or gate amplifier, in particularly a digitally controlled gate driver, to the input of a switching element or switching arrangement, that is higher than the maximum allowed voltage of the switching element or switching arrangement while assuring, by determining the currently occurring voltage at an internal gate port and a tap port respectively of the switching element and thus after circuit elements or parasitic elements, to not exceed a maximum allowed voltage at the internal gate port of the switching element.

These and other aspects will become apparent from and elucidated with reference to the following drawings.

Different embodiments are described with reference to different categories. However, all explanations and features equally apply to all of the switching arrangement, the switching circuit, the X-ray apparatus, the method for high-speed switching, the computer-readable medium, the program element, the processing device as well as the method for operating a device.

### BRIEF DESCRIPTION OF THE DRAWINGS

FIG. 1 shows an exemplary circuit diagram of a switching circuit/gate drive circuit according to the present invention;

FIGS. 2a,b show an exemplary embodiment of voltages and current measured in the switching circuit of FIG. 1;

FIGS. 3a,b show an exemplary operation of the comparator elements employed in the switching circuit of FIG. 1;

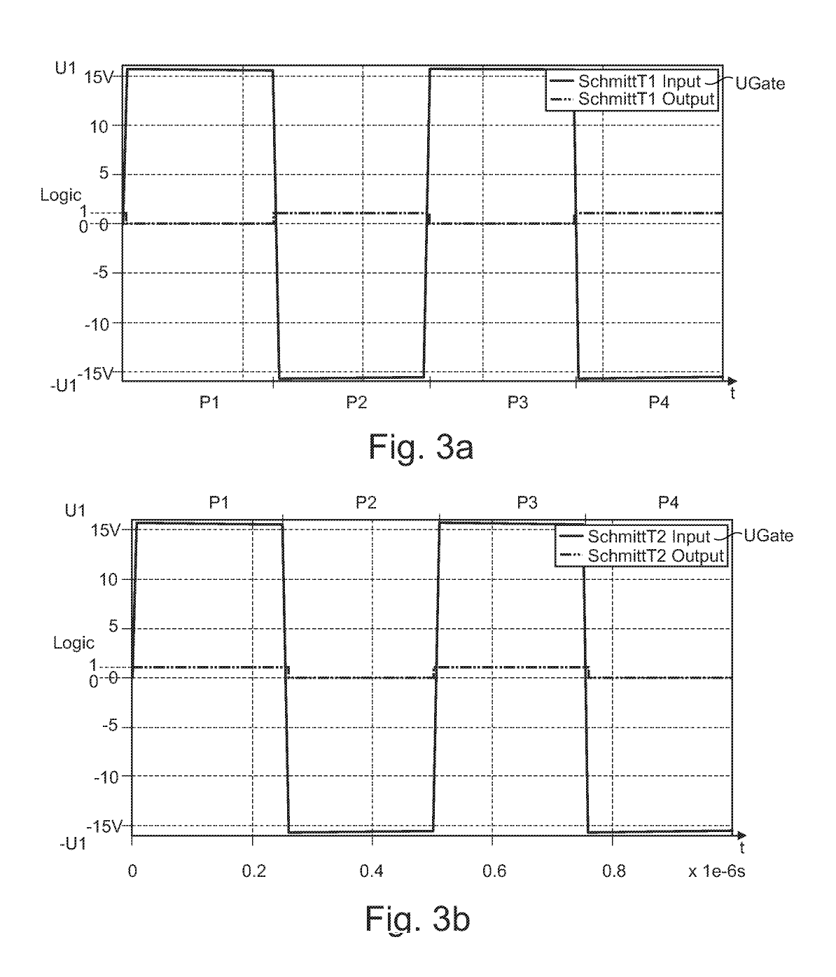

FIGS. 4a,b show a further exemplary embodiment of voltages and current measured in the switching circuit of FIG. 1;

FIGS. 5a,b show a further exemplary operation of the comparator elements employed in the switching circuit of FIG. 1;

FIGS. 6a,b show an exemplary embodiment of the comparator elements according to the present invention;

FIG. 7 shows an exemplary embodiment of a switching element employing a voltage tap according to the present invention;

FIG. 8 shows an exemplary embodiment of a method for high-speed switching according to the present invention; and

FIG. 9 shows an X-ray system employing a switching arrangement and a switching circuit according to the present invention.

### DETAILED DESCRIPTION OF EMBODIMENTS

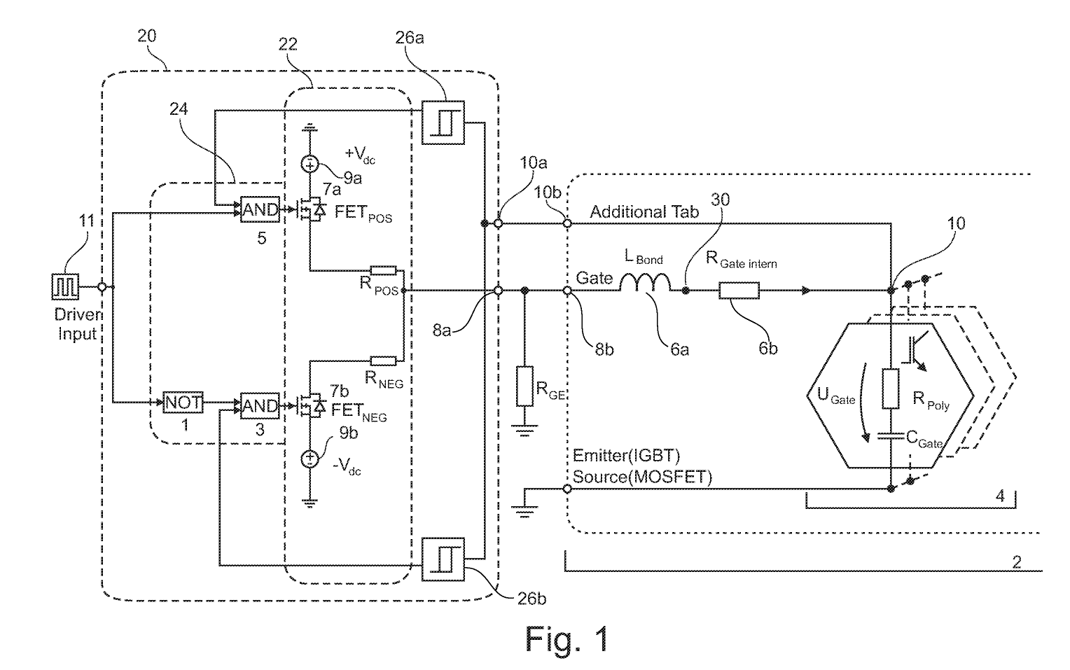

Now referring to FIG. 1, an exemplary circuit diagram of a switching circuit according to the present invention is depicted.

FIG. 1 shows the switching arrangement 2 as well as the switching circuit 20 in accordance with the present invention.

In particular, switching arrangement 2 is an analog part within switching circuit 20, which is a digital and analog circuit.

Switching arrangement 2 comprises, exemplarily, in FIG. 1 an insulating gate bipolar transistor, in particular a plurality of IGBTs provided in parallel, of which only the gate region of the first IGBT is depicted in detail, while an output port for switching a high voltage or high power comprising an emitter and a collector, is only depicted schematically. Further switching elements are feasible, e.g. a MOS-FET, in which case the output port rather comprises source and drain.

Switching arrangement 2 comprises input 8b, e.g. the gate pin of an IGBT or MOS-FET, at which input 8b an input voltage for switching is applied to switching arrangement 2, provided by gate driver output 8a of voltage source/gate amplifier 22, of a digitally controlled gate driver circuit 20. Parasitic elements like e.g. L_{bond} 6a and R_{gateintern} 6b, e.g. an internal gate resistor, are depicted exemplarily. L_{bond} 6a in particular may be a conductor, e.g. a bondwire, connecting input 8b with switching element 4.

Accordingly, input 8b may be seen as the input of switching arrangement 2 while the internal input port 10 may be seen as the input of switching element 4. Output 8a of gate amplifier 22 is exemplarily directly connected to input 8b.

Switching element 4, exemplarily depicted as an IGBT, comprises internal resistance R_{Poly} as well as internal capacitance C_{gate} due to its physical properties.

A voltage occurring at input 8b, due to parasitic element 6a and to the internal gate resistor 6b, is only provided to the internal gate port 10 with a certain delay, which delay is occurring due to the physics of parasitic element 6a and the internal gate resistor 6b. However, further parasitic elements, e.g. parasitic capacitance elements may be present as well.

Said delay between output 8a/input 8b and internal gate port 10 however is influencing the switching speed obtainable by switching element 4. In other words, parasitic element 6a and the internal gate resistor 6b decreases the maximum achievable switching speed of switching element 4.

Regularly, the maximum allowable input voltage for internal gate port 10 would also be applied to input 8b and would subsequently only arrive at the internal gate port in the previously described delayed manner.

Parasitic element 6a and the internal gate resistor 6b influences the slew rate of a signal applied to input 8b in such a way that said signal only arrives in a time-delayed manner at internal gate port 10/tap port 10b. In particular, a rise and fall of a voltage applied from output 8a to input 8b only arrives in a delayed manner at internal gate port 10.

Such a slew rate however is directly influenced by the voltage applied to input 8b. In other words, the higher the voltage applied to input 8b, the higher the slew rate and the smaller the delay until an applied voltage value, applied to input 8b, is also available at internal gate port 10 to switch on switching element 4.

In the context of the description, a maximum allowed internal gate voltage of switching element 4 is exemplarily given as ±15 V. In accordance with the gist of the invention, voltage source/gate amplifier 22, instead of providing ±15 V to input 8b to subsequently arrive at internal gate port 10, is rather providing a higher voltage or an overvoltage, e.g. ±50 V.

An increase from ±15 V to ±50 V also positively influences the slew rate of the voltage rise delay between input 8b and internal gate port 10. In other words, the time required for the internal gate voltage obtaining ±15 V is significantly reduced when applying ±50 V to input 8b rather than ±15 V. This reduction in time delay and thus increase in slew rate directly influences the maximum obtainable switching speed of switching element 4 and thus of switching arrangement 2 as well as switching circuit/gate drive circuit 20 and the complete switching circuit arrangement.

Voltage source 22 comprises a first voltage source 9a providing e.g. positive voltage U_{dc}, e.g. +50 V, connected to switching element 7a, e.g. exemplarily embodied a field effect transistor as well as negative voltage source 9b −U_{dc}, exemplarily providing −50 V to switching element 7b, again exemplarily embodied as a field effect transistor.

Switching elements 7a,b individually and exclusively provide +50 V and −50V respectively to input 8b by output 8a via resistors Rₚₒₛ and R_{neg}. AND elements 3 and 5 provide a switching signal to switching elements 7b,a respectively. AND element 5 is positively triggered, i.e. it provides a logic “1” to switching element 7a, i.e. switching on switching element 7a, so providing U_{dc} to input 8b, in case it receives a logic “1” from both pulse generator 11 as well as comparator element 26a, exemplarily embodied as a Schmitt trigger, in particular an inverse Schmitt trigger.

A logic “1” in this regard may e.g. providing a voltage of +5V to an input, while a logic “0” may correspond to 0V.

AND element 3 provides a logic “1” to switching element 7b in case pulse generator 11 delivers “0”, which signal is inverted by NOT element 1 to constitute a logic “1” and comparator element 26b providing logic “1”, also exemplarily embodied as Schmitt trigger, in particular an inverse Schmitt trigger.

Comparator elements 26a,b employ an analog input 10a, e.g. a gate driver feedback input port for a gate driver feedback signal, determining the internal gate voltage U_{gate} from tap port 10b and subsequently provide, depending on the determined voltage, a digital signal or logic “0” or “1”, depending on the detected or compared voltage U_{gate} with the maximum allowed gate voltage Uₘₐₓ. Uₘₐₓ in the exemplary embodiment of FIG. 1 corresponds to the aforementioned voltage of ±15 V.

In other words, with regard to Schmitt trigger 1, comparator 26a, a logic “1” is provided in case the determined voltage U_{gate} is below a voltage U₂, e.g. +14 V and provides logic “0” in case U_{gate} exceeds a voltage U₁, e.g. +15 V. Between U₁ and U₂, comparator 26a comprises a hysteresis, thus providing a logic value depending on the previous voltage curve. E.g., with U_{gate} starting from 0 V and rising, comparator 26a provides logic “1” until U_{gate} equals or exceeds U₁, e.g. +15 V, in which case Schmitt trigger 26a switches from logic “1” to “0”. Now, in case U_{gate} exceeded U₁ and is subsequently dropping, comparator 26a switches from logic “0” to “1” when falling below U₂ or e.g. +14V.

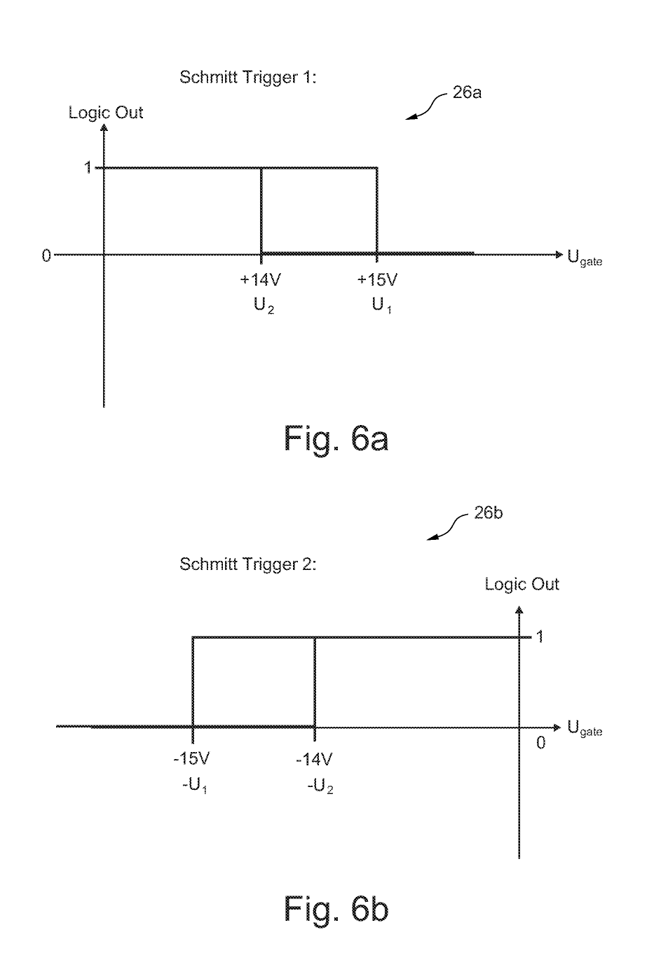

The same mode of operation applies to comparator 26b, with the exception that comparator 26b exemplarily operates in the negative voltage region, thus below 0 V with U₂=−14 V and U₁=−15 V. The working diagrams of comparator 26a and comparator 26b may be taken from FIGS. 6a,b.

While regular Schmitt trigger provide an analog output depending on the voltage input, comparator 26a,b further include an analog-to-digital converter element so providing a digital output “0” and “1”. Such an analog-to-digital converter element may be provided in addition to an “analog” Schmitt trigger or a combined element of an analog-to-digital converter element and Schmitt trigger may be employed.

With the individual elements of gate drive circuit 20 being explained, the working principle of gate drive circuit 20 itself will be explained in the following.

Driver input 11 provides a rectangular digital pulse signal or logic signal, e.g. alternating between +5V and 0V with a frequency of e.g. 100 kHz and an on/off ratio of 0.5. Each individual pulse phase of driver input 11 is subsequently referred to as P₁, P₂, P₃, P₄, etc.

Exemplarily, a pulse P₂ₙ₋₁ refers to a pulse having a logic “1”, while a pulse P₂ₙ refers to a pulse having a logic “0”, with n being an integer number.

Initially, circuit 20 is in an off-state, thus switching arrangement 2 as well as switching element 4 are in an off-position with U_{gate}=−15V. Accordingly, both comparator elements 26a,b provide logic “1”.

Assuming driver input 11 is providing logic “1”, AND element 5 receives logic “1” from driver input 11 while AND element 3, due to inverter or NOT element 1, receives logic “0”. The respective other input of AND elements 3, 5 is logic “1”, due to comparator elements 26a,b being logic “1” as described above.

Accordingly, only AND element 5 provides logic “1” to switching element 7a, which subsequently switches to an on-state, so providing voltage U_{dc} from voltage source 9a via Rₚₒₛ and output 8a to input 8b of switching arrangement 2. In other words, +50 V now is applied to input 8b.

Due to parasitic element 6a, the input voltage being applied to input 8b is not instantly provided to internal gate port 10 but rather with a certain time delay/slew rate. However, said time delay is less than a time delay, which would occur in case input port 8b would have been provided with +15 V only. Subsequently, input voltage is rising at tap port 10, so constituting internal gate voltage U_{gate}.

A rise in U_{gate} corresponds to a detected rise by comparator elements 26a,b via tap port 10b. After a certain time t₁, U_{gate} reaches the switching-on voltage of switching element 4, thus switching the output port to provide high voltage or high power to a subsequent consumer.

During all this time, U_{gate} is evaluated by comparator elements 26a,b via gate driver feedback input port 10a from tap port 10b. In case U_{gate} equals or exceeds, e.g. U₁ of comparator 26a, e.g. +15 V, comparator element 26a switches from logic “1” to logic “0”, resulting in only one input of AND element 5 receiving logic “1”, thus resulting in AND element 5 providing logic “0”, so switching off switching element 7a and thus not providing U_{dc} of voltage source 9a to input 8b anymore.

In case gate current I_{gate} in a switched-on phase substantially equals 0, no current is conducting through resistor R_{Poly} and thus no voltage drop occurs over R_{Poly} in accordance with Ohms Law, thus U_{gate}=U_{Cgate}. In other words, U_{gate} substantially remains constant for a full pulse phase P₁.

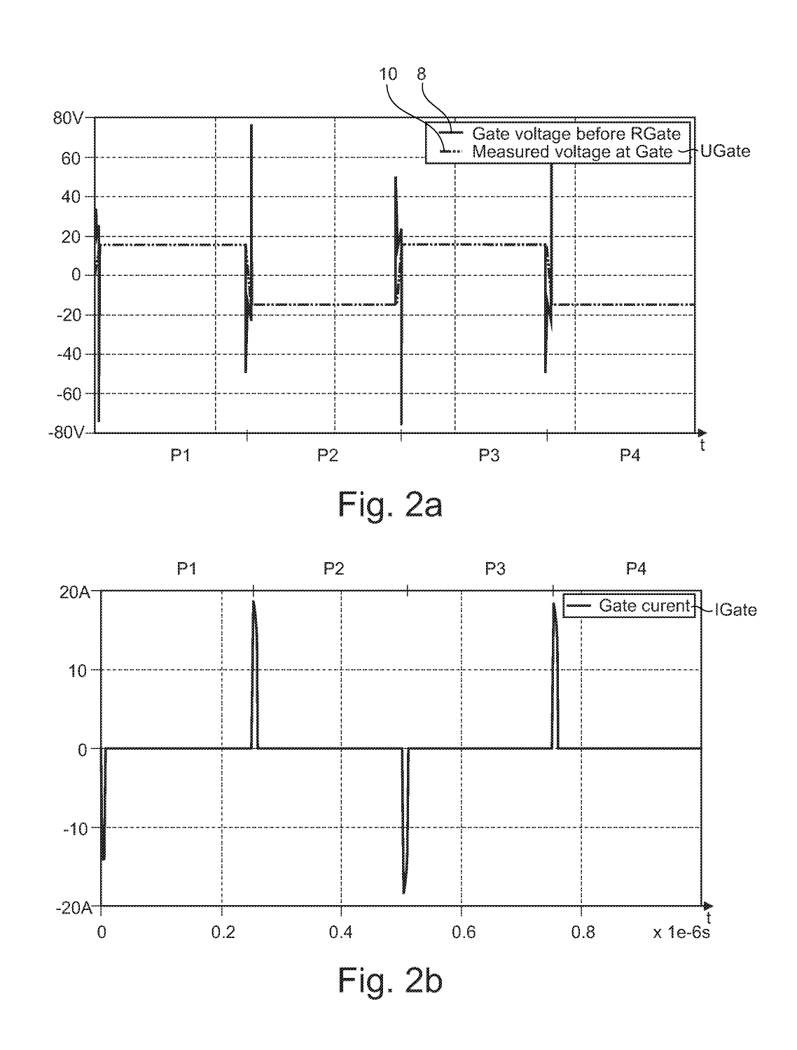

During this pulse, with U_{gate} substantially equaling Uₘₐₓ, comparator element 26a constantly outputs logic “0”, while comparator element 26b constantly outputs logic “1”. Said behavior may be deduced from FIGS. 2a,b and 3a,b.

For the next pulse P₂, pulse generator is switching from logic “1” to “0”. Consequently, the output of AND element 5 remains logic “0”, while the output of AND element 3 switches from logic “0” to “1”. Following, switching element 7b is switched on so providing negative voltage −U_{dc} from voltage source 9b via output 8a to input 8b, e.g. −50 V.

The afore-described behavior relating to pulse P₁ is thus inverted, subsequently U_{gate} equals −U₁, e.g. −15 V, thus switching off the output port of switching element 4. Individual pulse phases P₁, P₂, P₃, P₄, etc. are triggered by driver input 11, e.g. a pulse generator or an control CPU, in accordance with FIGS. 2a,b and 3a,b.

In case due to circuit element conditions, I_{gate} may not be assumed to be 0, a voltage drop over R_{Poly} may occur, resulting in a discharge of C_{gate}, so resulting in a voltage drop of U_{gate} over time within one pulse phase, so requiring an intermediate switching of a comparator element 26a,b, depending on ±U_{dc}, so that U_{gate} remains between U₁ and U₂ and −U₁ and −U₂ respectively.

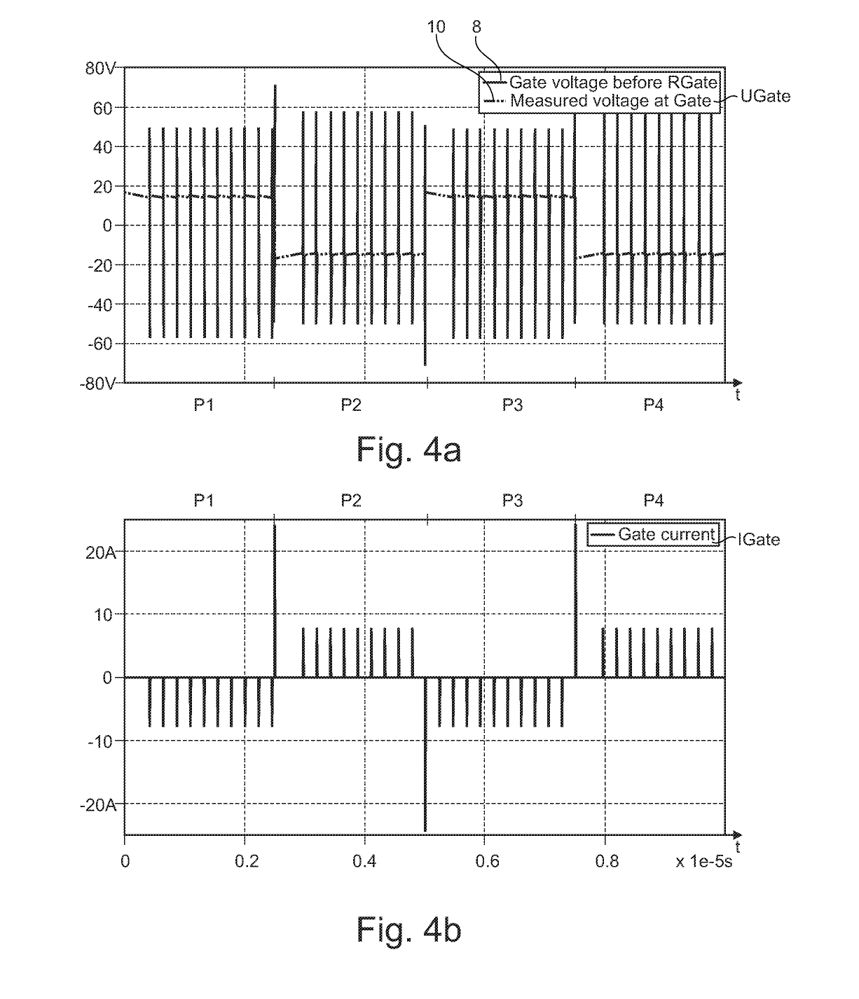

An according behavior of a switching circuit 20 may be taken from FIGS. 4a,b and 5a,b. With regard to FIG. 4a, in each pulse P₁, P₂, P₃, P₄, gate voltage U_{gate} is alternating between U₁ and U₂ and −U₁ and −U₂ respectively, as depicted by the saw tooth curve in FIG. 4a.

Referring exemplarily to P₁, each time U_{gate} exceeds U₁ comparator 26a is switched to logic “0”, subsequently not providing +U_{dc} of voltage source 9a via output 8a to input 8b any more, so resulting in a voltage drop of U_{gate}, due to a voltage drop over R_{Poly} and thus capacitance C_{gate} being discharged.

In case U_{gate} is passing below U₂, comparator element 26a again switches from logic “0” to “1”, again switching on switching element 7a so providing voltage U_{dc} from voltage source 9a to input 8b. This results in a subsequent rise of U_{gate} to U₁, again switching comparator 26a from logic “1” to “0”, subsequently switching off switching element 7a. This mode of operation is repeated multiple times during a single pulse Pₓ, until pulse generator 11 switches to a further pulse Pₓ₊₁.

In the following, exemplary ranges of occurring values are provided. +U_{dc} may be between 20 VDC and 100 VDC or even higher, Rₚₒₛ, R_{neg} may be between 0 Ohm and 5 Ohm, R_{GE} may be between 1 kOhm and 10 kOhm, L_{Bond} may be between 1 nH and 30 nH, R_{Gateintern} may be between 1 Ohm and 2 Ohm, R_{Poly} may be between 0 Ohm and 100 mOhm and C_{Gate} may be between 1 nF to 20 nF, each time including the respective range end values.

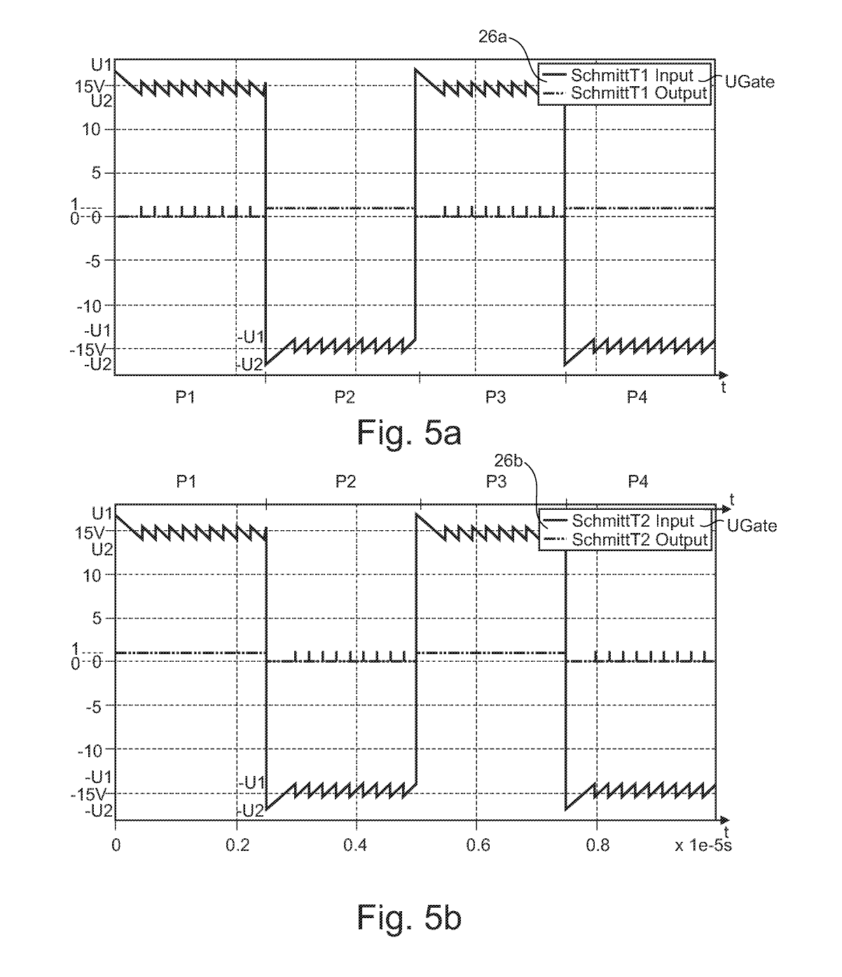

Now referring to FIGS. 5a,b, the input voltage is depicted at the respective comparator element 26a,b provided via tap port 10b, corresponding to U_{gate}. In positive pulse phases P₁, P₃, etc. U_{gate} is alternating between U₁ and U₂, e.g. +15 V and +14 V. As soon as U_{gate} reaches or exceeds U₁, comparator element 26a goes to logic “0” and in case U_{gate} goes below U₂, comparator element 26a goes to logic “1”, so subsequently switching on and off via switching element 7a voltage source 9a. This mode of operation may be seen in FIG. 5a by the spikes of logic “1” occurring, so intermediately providing U_{dc} via output 8a to input 8b for a brief time, resulting in the saw tooth voltage curve of U_{gate}.

The same mode of operation applies to negative pulses P₂, P₄, . . . with comparator 26b, switching element 7b and voltage source 9b.

Now referring to FIGS. 6a,b, again the mode of operation of the comparator elements 26a,b is depicted, embodied exemplarily as inverse Schmitt triggers. E.g. with regard to FIG. 6a and comparator 26a, logic “1” is provided starting from 0V until reaching U₁, e.g. +15 V, where the logic output goes to logic “0”. In case U₁ or U_{gate} drops, logic “0” is maintained until reaching or passing below U₂, e.g. +14 V, at which point the logic output reverts back to logic “1”.

The same mode of operation applies to comparator element 26b however, with negative voltages −U₁ and −U₂.

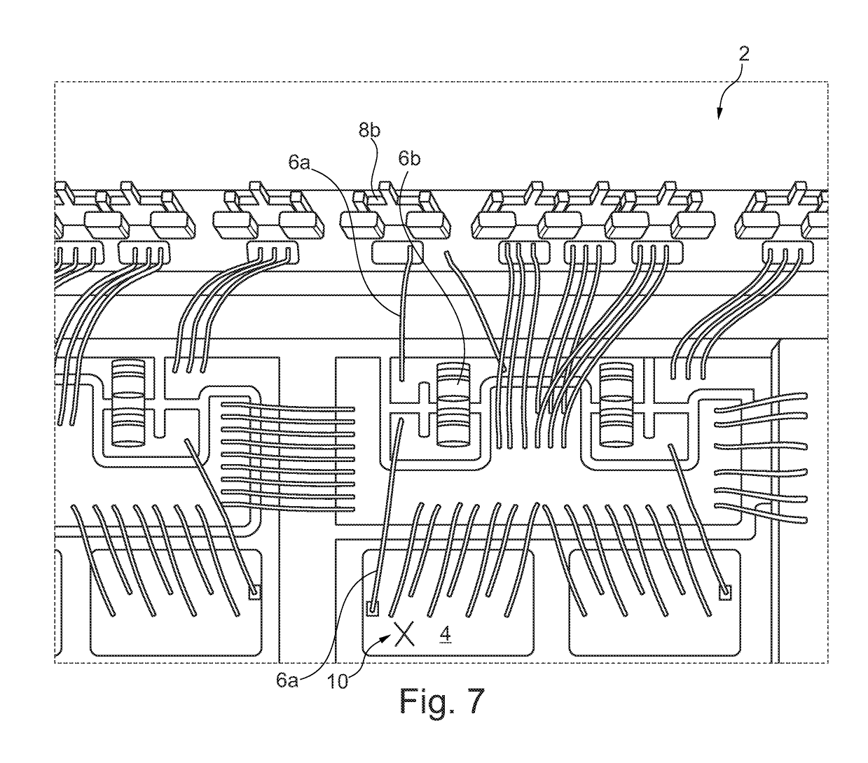

Now referring to FIG. 7, an exemplary embodiment of a switching element employing a voltage tap port 10b at the internal gate port 10 according to the present invention is depicted.

FIG. 7 shows the internal structure of the switching arrangement 2, in particular exemplarily an IGBT module, also comprising switching element 4, which is only schematically depicted. Input 8b is indicated for providing voltage from gate amplifier 22 to switching arrangement 2. The conductors having an inductance L_{bond} 6a is depicted as well as parasitic resistor R_{gateintern} 6b, subsequently arriving at tap port 10b from where U_{gate} may be measured by providing U_{gate} to gate driver feedback input port 10a.

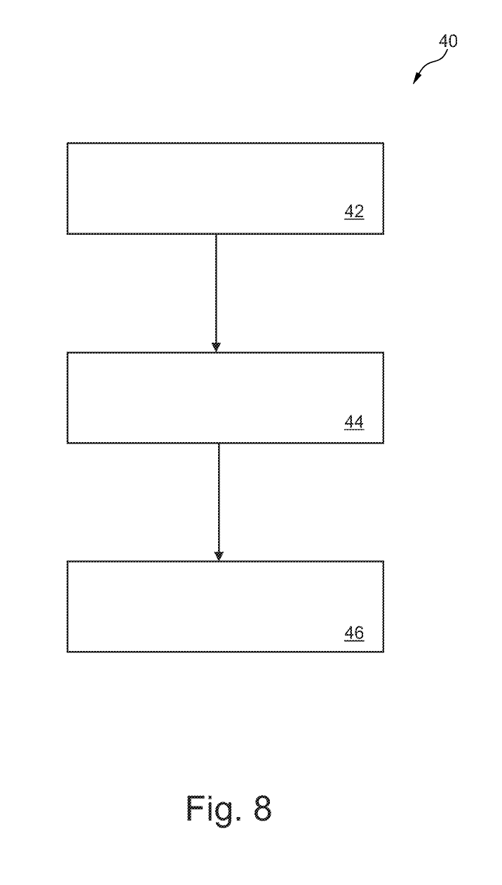

Now referring to FIG. 8, an exemplary embodiment of a method for high-speed switching according to the present invention is depicted.

FIG. 8 shows a method 40 for high-speed switching comprising the steps of applying 42 an input voltage to an input 8b of a switching arrangement 2, detecting 44 an internal gate voltage at the internal gate port 10 of a switching element 4 and controlling 46 the voltage of a gate amplifier 22 so as not to exceed a maximum internal gate voltage defined for internal gate port 10, wherein a circuit element 6a,b is arranged between input 8b and internal gate port 10 of switching arrangement 2 and wherein the input voltage is higher than the maximum internal gate voltage U_{gate}.

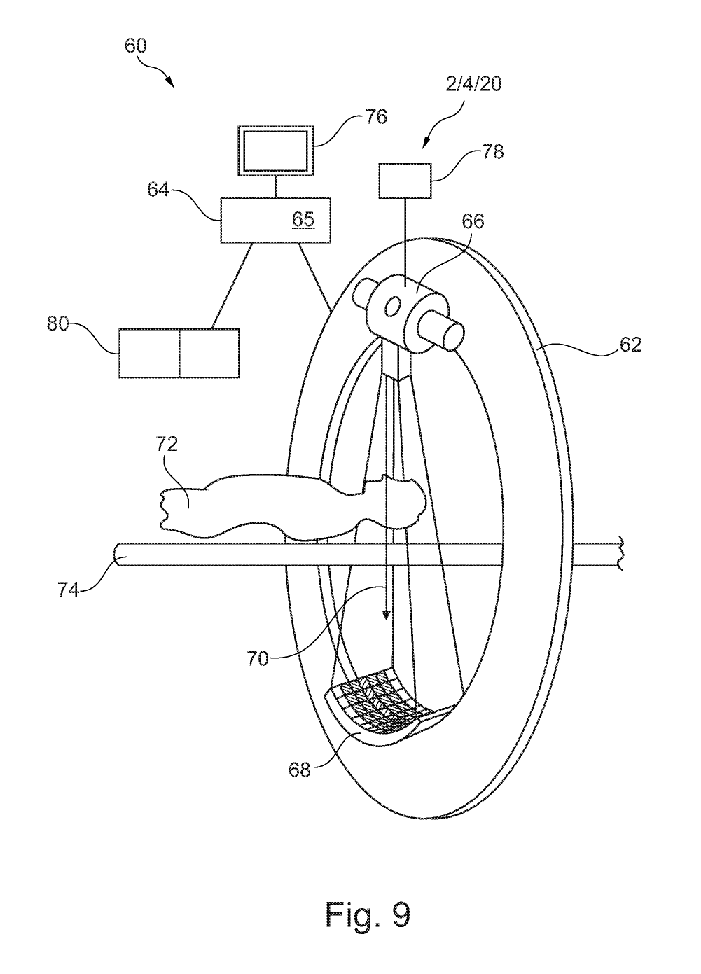

Now referring to FIG. 9, an X-ray system employing a switching arrangement and/or a switching circuit according to the present invention is depicted.

FIG. 9 shows X-ray system 60, exemplarily embodied as a CT-system. X-ray generating device 66, e.g. an X-ray tube, is arranged opposite X-ray detector 68, mounted on gantry 62 for rotation about an object 72 and is adapted for generating X-radiation 70. X-radiation 70 is directed towards X-ray detector 68, with X-ray generating device 66 and X-ray detector 68 being operatively coupled so that X-ray image information may be acquired of object 72, e.g. a patient, arranged in the path of X-radiation 70. Object 72 is situated on support 74.

In X-ray system 60, a high voltage generator 78 is provided employing a switching arrangement 2, a switching circuit/gate drive circuit 20 and/or a switching circuit arrangement comprising switching element 4.

Circuit 20 with switching arrangement 2 is providing a high voltage to X-ray generating device 66 for generation of X-radiation 70.

Processing device 64 is provided for controlling high voltage generator 78 and in particular switching element 4, switching arrangement 2 and/or circuit 20, to provide a high voltage to X-ray generating device 66. Processing device 64 comprises a program element for controlling switching element 4, switching arrangement 2 and/or switching circuit 20. Processing device 64 further comprises a processing element 65 or microprocessor.

Acquired X-ray information may be provided via display element 76 to a user, who may control processing device 64 via interface unit 80.

### LIST OF REFERENCE SIGNS

1 Inverter element/NOT element
2 Switching arrangement (IGBT or MOSFET module)
3 AND element
4 Switching element (Cell)
5 AND element
6a,b Circuit elements/parasitic elements
7a,b Switching elements
8a Output/gate driver output
8b Input of switching arrangement
9a,b Voltage source
10 internal input port/gate port having an internal gate voltage U_{gate}
10a Gate driver feedback input signal
10b Tap port
11 Driver Input/Gate driver input (e.g. pulse generator or control CPU)
20 Digitally controlled Gate driver/switching circuit
22 Gate driver amplifier circuit/amplifier circuit/voltage source
24 Control logic/input voltage source control element/gate driver control logic circuit
26a,b internal gate port voltage detection element
30 Internal point parasitic elements
40 Method for high-speed switching
42 STEP: Applying an input voltage
44 STEP: Detecting an internal gate port voltage
46 STEP: Controlling the input voltage
60 CT X-ray system
62 Gantry
64 Processing device
65 Processing element
66 X-ray generating device/X-ray tube
68 X-ray detector
70 X-radiation
72 Object/Patient
74 Support/Table
76 Display element
78 High Voltage Generator
80 Interface Unit

1. Switching arrangement (2), comprising
an input (8b), and
at least one switching element (4), comprising
an internal gate port (10); and
an output port;
wherein the switching element (4) is adapted for switching a high voltage at the output port in response to a voltage received at the internal gate port (10);
wherein a maximum internal gate voltage is defined for the internal gate port (10);
wherein at least one circuit element (6a,b) is arranged between the input (8b) and the internal gate port (10); and
wherein the switching element (4) comprises a tap port (10b) for providing the current internal gate voltage U_{gate}.

2. Switching arrangement (2) according to claim 1,
wherein the switching element (4) is at least one element out of the group consisting of a transistor element, an insulated gate bipolar transistor (IGBT) and a metal oxide semiconductor field-effect transistor (MOS-FET).

3. Switching arrangement (2) according to claim 1,
wherein the circuit element (6a,b) is at least one element out of the group consisting of a resistor, an inductance, a capacitance, a parasitic element, a parasitic resistor, a parasitic inductance, a parasitic capacitance, an element effecting a voltage drop between the input and the internal gate port (10) and an element effecting a change in a slew rate of the input signal between the input and the internal gate port (10).

4. Switching circuit (20) for high speed switching, comprising
an amplifier circuit (22), comprising
an output (8a) being adapted to be connectable to an input (8b) of a switching arrangement (2) according to claim 1,
wherein the voltage provided by the output (8a) exceeds a maximum internal gate voltage;
wherein the amplifier circuit (22) is controllable so that a current internal gate voltage does not to exceed the maximum internal gate voltage.

5. Switching circuit (20) according to claim 4, further comprising
an internal gate port voltage determination element (26a,b) connectable to a tap port (10b) for determining the current internal gate voltage U_{gate}; and
a voltage source control element (24) for controlling the voltage at the output (8a);
wherein the input voltage determination element (26a,b) and the input voltage source control element (24) are operatively coupled such that the amplifier circuit (22) is controllable to provide a voltage by output (8a) to an input (8b) so that a current internal gate voltage does not to exceed the defined maximum internal gate voltage.

6. Switching circuit according to claim 4, the amplifier circuit (22) comprising
at least one voltage source (9a,b), and
at least one switching element (7a,b), coupled to the at least one voltage source (9a,b);
wherein the switching element (7a,b) is adapted to switch on and off the voltage at the output (8a) by switching on and off the at least one voltage source (9a,b).

7. Switching circuit according to claim 4,
wherein the internal gate voltage determination element (26a,b) is a comparator element for comparing the current internal gate voltage U_{gate} and the defined maximum internal gate voltage.

8. Switching circuit according to claim 4,
wherein the voltage source control element (24) is adapted for switching the at least one switching element (7a,b) for controlling the voltage of output port (8a), wherein the voltage source control element (24) is in particular a digital switching logic for switching the at least one voltage source (9a,b) of the amplifier circuit (22).

9. Switching circuit according to claim 2,
wherein the internal gate port voltage determination element (26a,b) comprises an analog to digital converter to output a digital control signal in response to the analog current internal gate voltage U_{gate} at tap port (10b).

10. Switching circuit arrangement, comprising
a switching circuit (20) according to one of claims 4 to 9
wherein the switching element (4) comprises a tap port (10b) for providing the current internal gate voltage U_{gate}; and
wherein the tap port (10b) is connected to a gate driver feedback input port of voltage determination element (26a,b).

11. X-ray apparatus (60), comprising one of a switching arrangement (2), switching circuit (20) and a switching circuit arrangement according to claim 10.

12. Method (40) for high speed switching, comprising the steps of
applying (42) a voltage to an input (8b) of a switching arrangement (2);
detecting (44) an internal gate voltage at an additional tap port of a switching element (4) of the switching arrangement (2); and
controlling (46) the voltage so as not to exceed at the internal gate port (10) a maximum internal gate voltage defined for the internal gate port (10);
wherein at least one circuit element (6a,b) is arranged between the input (8b) and the internal gate port (10); and
wherein the voltage is higher than the maximum internal gate voltage.

13. A computer readable medium, in which a computer program is stored for performing a method according to claim 12.

14. A program element (76), wherein the program element, when being executed, controls a switching circuit according to claim 1.

15. A processing device (64) in which a computer program is executed, wherein the processing device is adapted to control a switching circuit according to claim 1.
